(19) United States
(12) Patent Application Publication
(10) Pub. No.: US 2026/0169090 A1
(43) Pub. Date: Jun. 18, 2026

(54) APPARATUS AND METHOD FOR MEASURING OPEN CIRCUIT VOLTAGE OF BATTERY CELL

(71) Applicant: SAMSUNG SDI CO., LTD., Yongin-si (KR)

(72) Inventor: Hui Yun BAK, Suwon-si (KR)

(21) Appl. No.: 19/211,637

(22) Filed: May 19, 2025

(30) Foreign Application Priority Data
Dec. 16, 2024 (KR) 10-2024-0187276

(51) Int. Cl. G01R 31/396; G01R 31/371; G01R 31/3835

(52) U.S. Cl. CPC G01R 31/396; G01R 31/371; G01R 31/3835

(57) ABSTRACT

An apparatus for measuring an open circuit voltage of a battery cell includes a substrate, a connector on the substrate, a board configured to measure the open circuit voltage of the battery cell, and a processor configured to control the board to measure the open circuit voltage of the battery cell when the connector is connected to a terminal of the battery cell.

### CROSS-REFERENCE TO RELATED APPLICATION

This application claims priority to and the benefit of Korean Patent Application No. 10-2024-0187276, filed on December 16, 2024, the disclosure of which is incorporated herein by reference in its entirety.

### BACKGROUND

### 1. Field

The present disclosure relates to an apparatus and a method for measuring an open circuit voltage (OCV) of a battery cell.

### 2. Description of the Related Art

In a battery production process, a formation process takes up much space and production lead time.

The formation process includes detailed unit processes such as an aging process, a battery cell open circuit voltage (OCV) measurement process, and a good/bad product selection process, and only battery cells that are ultimately determined as good products in the formation process are shipped to the module line or customer.

The above information disclosed in this Background section is for enhancement of understanding of the background of the present disclosure, and therefore, it may contain information that does not constitute related (or prior) art.

### SUMMARY

Embodiments relate to an apparatus for measuring an open circuit voltage of a battery cell, the apparatus including a substrate, a connector on the substrate, a board configured to measure the open circuit voltage of the battery cell, and a processor configured to control the board to measure the open circuit voltage of the battery cell when the connector is connected to a terminal of the battery cell.

The substrate may be a cover of a tray.

The apparatus may further include a communication part providing a communication interface with an external device, wherein the processor may be further configured to transmit the open circuit voltage of the battery cell to the external device through the communication part.

The connector may be on a bottom surface of the substrate.

The connector may correspond to a position where the battery cell is on a tray.

The processor may be further configured to match the open circuit voltage of the battery cell to identification information for the battery cell.

The identification information may include position information on a position where the battery cell is on a tray.

The apparatus may further include a substrate position adjustment part configured to adjust a position of the substrate according to a control signal of the processor, and connect the connector to the terminal of the battery cell.

The apparatus may further include a substrate position detector configured to detect a position of the substrate and transmit the position to the processor.

Embodiments include a method of measuring an open circuit voltage of a battery cell, the method including controlling, by a processor, a substrate position adjustment part to connect a connector formed on a substrate to a terminal of a battery cell, and controlling, by the processor, a board to measure an open circuit voltage of the battery cell.

Connecting the connector to the terminal of the battery cell may include detecting, by a substrate position detector, a position of the substrate, disposing, by the processor, the substrate at a preset target position through the substrate position adjustment part according to the position of the substrate, and connecting the connector to the terminal of the battery cell.

The method may further include controlling, by the processor, a communication part to transmit the open circuit voltage of the battery cell to an external device.

Transmitting the open circuit voltage of the battery cell to the external device may include the processor matching the open circuit voltage of the battery cell to identification information set for the battery cell.

The identification information may include position information on a position where the battery cell is disposed on a tray.

The substrate may be formed as a cover of a tray.

The method may further include forming the connector on a bottom surface of the substrate.

The method may further include forming the connector to correspond to a position where the battery cell is disposed on a tray.

### BRIEF DESCRIPTION OF THE DRAWINGS

Features will become apparent to those of ordinary skill in the art by describing in detail exemplary embodiments with reference to the attached drawings, in which:

FIG. 1 is a block diagram illustrating an apparatus for measuring an open circuit voltage (OCV) of a battery cell according to an embodiment of the present disclosure;

FIG. 2 is an exemplary diagram illustrating a tray on which battery cells are disposed according to an embodiment of the present disclosure;

FIG. 3 is a perspective view illustrating a substrate according to an embodiment of the present disclosure;

FIG. 4 is a side view illustrating the substrate according to an embodiment of the present disclosure;

FIG. 5 is a diagram illustrating a horizontal movement of the substrate according to an embodiment of the present disclosure;

FIG. 6 is a diagram illustrating a vertical movement of the substrate according to an embodiment of the present disclosure;

FIG. 7 is an exemplary diagram illustrating a connection between a connector and a terminal according to an embodiment of the present disclosure; and

FIG. 8 is a flowchart illustrating a method of measuring an OCV of a battery cell according to an embodiment of the present disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her disclosure in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being "coupled" or "connected" to a second element, the first element may be directly coupled or connected to the second element or the first element may be indirectly coupled or connected to the second element via one or more intervening elements.

As used herein, the term “and/or” includes any and all combinations of one or more of the associated listed items. Further, the use of "may" when describing embodiments of the present disclosure relates to "one or more embodiments of the present disclosure." Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms "substantially," "about," and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or "over" the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms "includes," "including," “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of "1.0 to 10.0" is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

When an arbitrary element is referred to as being disposed (or located or positioned) on the "above (or below)" or "on (or under)" a component, it may mean that the arbitrary element is placed in contact with the upper (or lower) surface of the component and may also mean that another component may be interposed between the component and any arbitrary element disposed (or located or positioned) on (or under) the component.

In addition, it will be understood that when an element is referred to as being “coupled,” “linked” or "connected" to another element, the elements may be directly “coupled,” “linked” or "connected" to each other, or an intervening element may be present therebetween, through which the element may be “coupled,” “linked” or “connected” to another element. In addition, when a part is referred to as being "electrically coupled" to another part, the part can be directly connected to another part or an intervening part may be present therebetween such that the part and another part are indirectly connected to each other.

Throughout the specification, when "A and/or B" is stated, it means A, B or A and B, unless otherwise stated. That is, “and/or” includes any or all combinations of a plurality of items enumerated. When "C to D" is stated, it means C or more and D or less, unless otherwise specified.

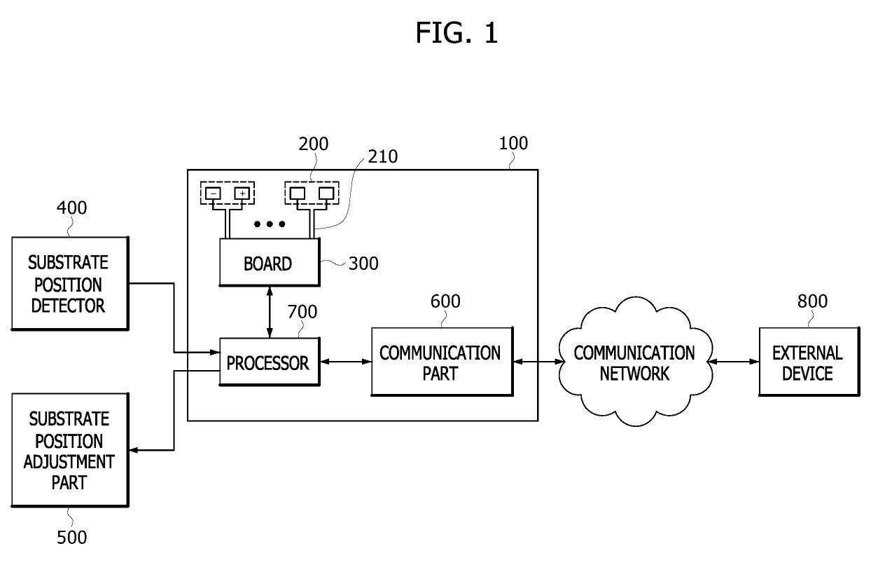

FIG. 1 is a block diagram illustrating an apparatus for measuring an open circuit voltage (OCV) of a battery cell according to an embodiment of the present disclosure.

Referring to FIG. 1, the apparatus for measuring an OCV of a battery cell according to an embodiment of the present disclosure may include a substrate 100, a plurality of connectors 200, a board 300 (e.g., printed circuit board), a substrate position detector 400, a substrate position adjustment part 500, a communication part 600, and a processor 700.

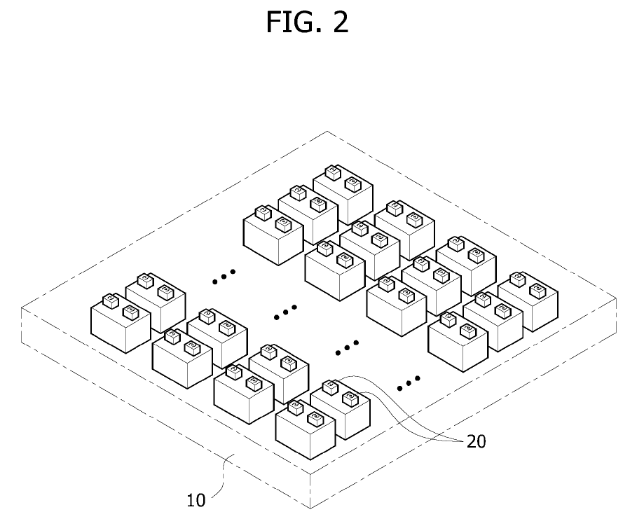

The substrate 100 allows the plurality of connectors 200, which cover a plurality of battery cells 20 (see FIG. 2) disposed inside a tray 10 and are disposed on a bottom surface of the substrate 100, to be electrically connected to the plurality of battery cells 20. The plurality of connectors 200 will be described below. Here, the plurality of connectors 200 and the plurality of battery cells 20 being connected may mean that the plurality of connectors 200 and the plurality of battery cells 20 are in physical contact with each other and thus an electrical signal is (e.g., electrical signals are) transmitted therebetween.

The substrate 100 may be formed in the form of a cover of the tray 10 on which the battery cells 20 are disposed. For example, the substrate 100 may be formed in a plate shape.

The battery cells 20 may be disposed inside the tray 10 to undergo a formation process.

The formation process is a process performed for optimizing/maximizing performance of a battery before the battery is assembled and then shipped to the market. The formation process may include a charging/discharging process of charging and discharging the plurality of battery cells 20, an aging process of storing the battery, a degassing process of removing internal gases generated during the charging/discharging process and the aging process, and a test process of measuring OCVs of the plurality of battery cells 20.

FIG. 2 is an exemplary diagram illustrating a tray on which battery cells are disposed according to an embodiment of the present disclosure.

Referring to FIG. 2, the plurality of battery cells 20 may be disposed and stored on the tray 10. For example, 100 battery cells 20 may be stored on the tray 10, but the number of battery cells 20 stored on the tray 10 may vary.

The plurality of connectors 200 may be disposed on a bottom surface of the substrate 100.

The plurality of connectors 200 may be disposed on the bottom surface of the substrate 100. The plurality of connectors 200 may be disposed at a position corresponding to an arrangement position of the plurality of battery cells 20 on the tray 10.

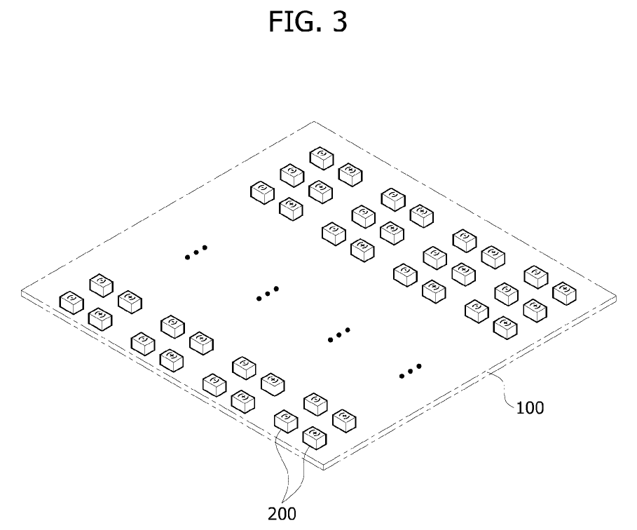

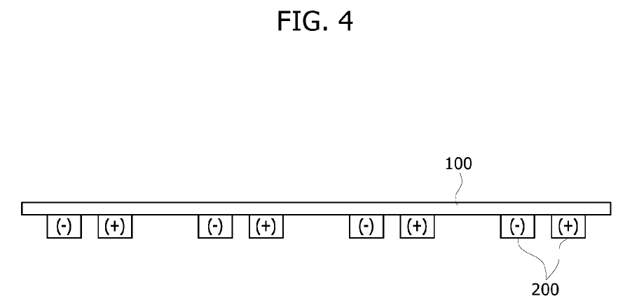

FIG. 3 is a perspective view illustrating the substrate 100 according to an embodiment of the present disclosure, and FIG. 4 is a side view illustrating the substrate 100 according to an embodiment of the present disclosure.

Referring to FIGS. 3 and 4, the plurality of connectors 200 may be on the bottom surface of the substrate 100.

The plurality of connectors 200 may include a positive electrode terminal and a negative electrode terminal. The positive electrode terminal of the plurality of connectors 200 may be connected to a positive electrode terminal 30 of the plurality of battery cells 20, and the negative electrode terminal of the plurality of connectors 200 may be connected to a negative electrode terminal 31 of the plurality of battery cells 20. Accordingly, the board 300 (see FIG. 1) is electrically connected to the plurality of battery cells 20, and thus an OCV of the plurality of battery cells 20 may be measured.

The plurality of connectors 200 may be formed to protrude downward (see FIG. 4) and come into contact with the terminals (e.g., the positive electrode terminal 30 and the negative electrode terminal 31) of the plurality of battery cells 20. In this way, the plurality of connectors 200 may be more easily connected to the terminals of the plurality of battery cells 20.

In the present embodiment, an example in which the plurality of connectors 200 are formed to protrude to come into contact with the plurality of battery cells 20 will be described. However, the plurality of connectors 200 may be formed in various ways according to the shape or size of the terminal of the plurality of battery cells 20 or an electrical connection method. For example, the plurality of connectors 200 may be formed to be recessed inside the substrate 100 so that the positive electrode terminal 30 and the negative electrode terminal 31 of the plurality of battery cells 20 is inserted into an inner space of the substrate 100.

The plurality of connectors 200 may be detachable from the substrate 100. The plurality of connectors 200 may be formed in various structures according to the positive electrode terminal 30 and the plurality of battery cells 20. Accordingly, the plurality of connectors 200 may be selectively mounted on the substrate 100 according to the positive electrode terminal 30 and the negative electrode terminal 31 of the plurality of battery cells 20 and connected to the terminals of the corresponding battery cell of the battery cells 20.

In detail, the positive electrode terminal 30 and the negative electrode terminal 31 of the plurality of battery cells 20 may be manufactured in various ways according to a type or structure of the plurality of battery cells 20. In this case, the plurality of connectors 200 are connected to the terminals of various shapes and sizes or electrical connection methods. Accordingly, connectors 200 suitable for the positive electrode terminal 30 and the negative electrode terminal 31 of the plurality of battery cells 20 may be selected and connected to the terminals of the plurality of battery cells 20 of various structures, and the plurality of connectors 200 may be mounted on the substrate 100, thereby enabling OCV measurement for various types of battery cells.

The plurality of connectors 200 may be installed to correspond to arrangement positions and a maximum number of the plurality of battery cells 20 on the tray 10. For example, when 100 battery cells are disposed on the tray 10, 100 connectors 200 may be disposed on the substrate 100. When the battery cells are disposed in the form of a matrix on the tray 10, the connectors 200 may also be disposed in the form of a matrix corresponding to the arrangement positions of the plurality of battery cells 20 on the substrate 100.

Meanwhile, in addition to the plurality of connectors 200, the board 300, the communication part 600, and the processor 700 may be installed on the substrate 100. However, the board 300, the communication part 600, and the processor 700 may be installed separately from the substrate 100.

The substrate 100 may be installed to be movable in a horizontal direction or a vertical direction. In this way, a position of the substrate 100 may be adjusted so that the plurality of connectors 200 and the positive electrode terminal 30 of the plurality of battery cells 20 may be accurately connected. This will be described below.

The board 300 may detect an OCV of the plurality of battery cells 20. The board 300 may be connected to the plurality of connectors 200 through an electrical line 210 (see FIG. 1). When the plurality of connectors 200 is connected to the positive electrode terminal 30 and the negative electrode terminal 31, the board 300 is electrically connected to the plurality of battery cells 20, and thus an OCV of the battery may be measured.

The board 300 may measure the OCV of the plurality of battery cells 20 through a current sensor, a voltage sensor, a timer, a temperature sensor, etc. Here, the sensors may be installed separately from the board 300 or installed in the board 300.

The substrate position detector 400 may detect a position of the substrate 100. The substrate position detector 400 may be an image sensor that captures the substrate 100 and detects a position of the substrate 100 through image analysis, a laser sensor that detects the position of the substrate 100 through a time it takes a laser to be emitted toward the substrate 100 and then reflected and returned therefrom, or an ultrasonic sensor that detects the position of the substrate 100 through a time it takes an ultrasonic wave to be emitted toward the substrate 100 and then reflected and returned therefrom. The substrate position detector 400 may be selected in various ways according to a working environment immediately before the tray 10 is put into an aging rack.

The substrate position adjustment part 500 adjusts the position of the substrate 100 to allow the plurality of connectors 200 to be accurately connected to the positive electrode terminal 30 and the negative electrode terminal 31 of each of the plurality of battery cells 20.

The substrate position adjustment part 500 may adjust the position of the substrate 100. The substrate position adjustment part 500 may move the position of the substrate 100 in a horizontal direction or a vertical direction to improve accuracy of a connection between the plurality of connectors 200 and the terminals of the plurality of battery cells 20. The substrate position adjustment part 500 may be a transport device such as an orthogonal robot for adjusting the position of the substrate 100, but may vary.

The processor 700 may be connected to a memory and may execute a command stored in the memory. The processor 700 may control at least one other component (e.g., a hardware or software component) connected to the processor 700 by executing the command stored in the memory and perform processing or calculation on a variety of data.

The memory may store a variety of data used by the processor 700. The data may include commands for performing actions or operations according to embodiments of the present disclosure. That is, the memory may store commands that enable measuring the OCVs of the plurality of battery cells 20 and transmitting and receiving the measured OCVs in a wireless manner.

The memory may include at least one storage medium among a flash memory type memory, a hard disk type memory, a multimedia card micro type memory, a card type memory, a random access memory (RAM), a static random access memory (SRAM), a read-only memory (ROM), a programmable read-only memory (PROM), an erasable programmable read-only memory (EPROM), and an electrically erasable programmable read-only memory (EEPROM).

In addition, a component of the processor 700 for performing each function may be formed separately on a hardware, software, or logic level. In this case, dedicated hardware may be used to perform each function. To this end, the processor 700 may be implemented as or may include at least one among an application specific integrated circuit (ASIC), a digital signal processor (DSP), a programmable logic device (PLD), field programmable gate arrays (FPGAs), a central processing unit (CPU), microcontrollers, and/or microprocessors.

The processor 700 may be implemented as a CPU or a system on chip (SoC), may run an operating system or an application to control a plurality of hardware or software components connected to the processor 700, and may perform various data processing and various arithmetic operations. The processor 700 may execute at least one command stored in the memory and store execution result data in the memory.

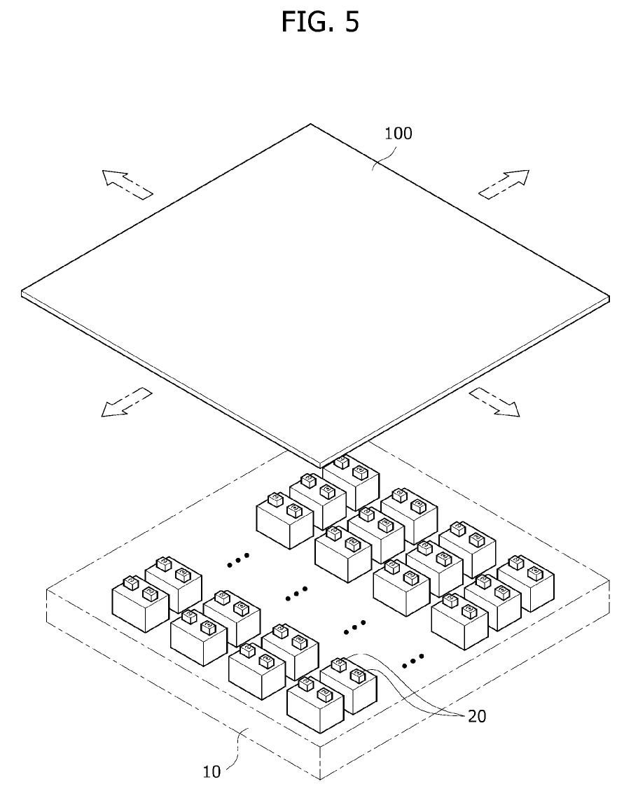

The processor 700 controls the substrate position detector 400 to detect the position of the substrate 100 and controls the substrate position adjustment part 500 according to the detected position of the substrate 100 to allow the plurality of connectors 200 to be connected to the terminals of the plurality of battery cells 20. This will be described with reference to FIGS. 5 to 7.

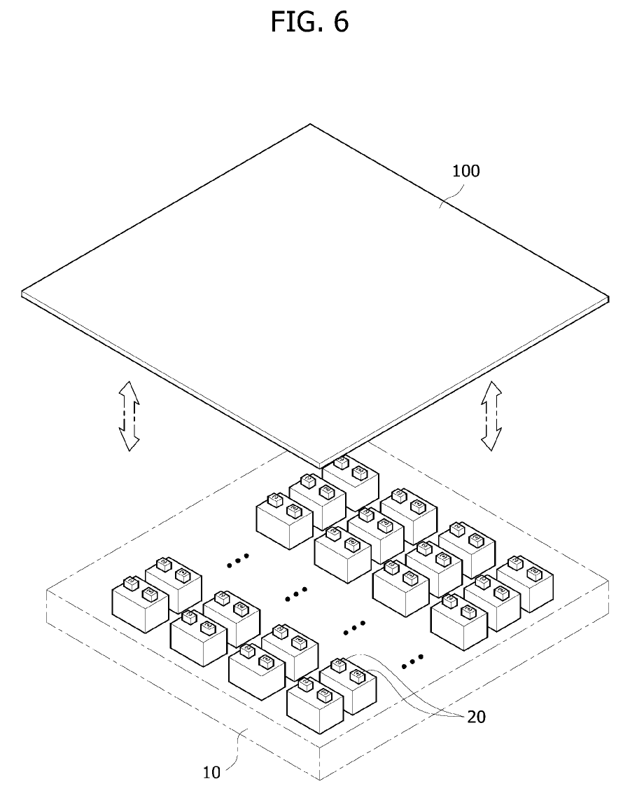

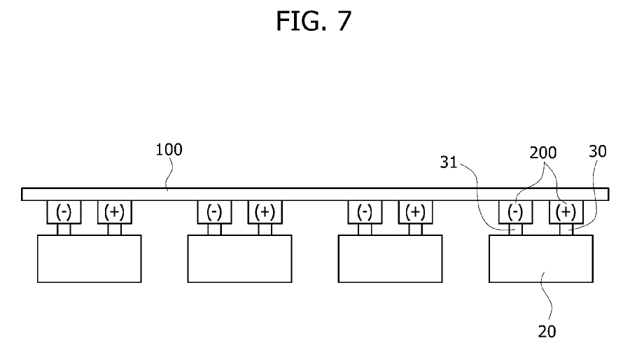

FIG. 5 is a diagram illustrating a horizontal movement of the substrate according to an embodiment of the present disclosure, FIG. 6 is a diagram illustrating a vertical movement of the substrate according to an embodiment of the present disclosure, and FIG. 7 is an exemplary diagram illustrating a connection between a connector and a terminal according to an embodiment of the present disclosure.

First, the processor 700 may check whether the position of the substrate 100 detected by the substrate position detector 400 corresponds to a preset target position.

The target position may be a position of the substrate 100 where the plurality of connectors 200 may be precisely connected to the terminals of the plurality of battery cells 20.

As shown in FIGS. 5 and 6, when the position of the substrate 100 is different from the target position, the processor 700 controls the substrate position adjustment part 500 to move the substrate 100 in a horizontal direction or a vertical direction to allow the substrate 100 to be disposed at the target position.

As shown in FIG. 7, when the substrate 100 is disposed at the target position, the plurality of connectors 200 is connected to the positive electrode terminal 30 and the negative electrode terminal 31 of each of the plurality of battery cells 20.

Here, when the substrate 100 is disposed at the target position, all the connectors 200 of the substrate 100 are simultaneously connected to all the terminals of the plurality of battery cells 20.

In this way, since the plurality of connectors 200 is connected to the terminals of the plurality of battery cells 20, the board 300 is electrically connected to the plurality of battery cells 20 through the plurality of connectors 200. In this case, the board 300 may measure the OCV of the plurality of battery cells 20 according to a control signal of the processor 700.

The processor 700 may control the board 300 to measure the OCV of the plurality of battery cells 20.

Identification information for identifying the plurality of battery cells 20 may be set in the processor 700.

The identification information may be set for each position where each of the plurality of battery cells 20 is disposed on the tray 10. The identification information may be position information on a position where each of the plurality of battery cells 20 is disposed on the tray 10. That is, the plurality of battery cells 20 are disposed on the tray 10, and each of the plurality of battery cells 20 may be disposed at a preset position on the tray 10. Therefore, when the plurality of battery cells 20 are disposed on the tray 10, identification information may be automatically matched to a corresponding battery cell of the plurality of battery cells 20. For example, when 100 of the plurality of battery cells 20 are disposed on the tray 10, the 100 battery cells may be matched to 100 pieces of identification information according to their positions on the tray 10 in a one-to-one manner. The identification information may vary, as long as it can identify the plurality of battery cells 20 on the tray 10.

The processor 700 may determine whether the plurality of battery cells 20 is connected, determine whether the OCV is measured, and manage the OCV on the basis of the identification information.

In detail, the processor 700 may identify the plurality of battery cells 20 currently disposed on the tray 10 on the basis of the identification information. For example, when the plurality of connectors 200 is connected to the positive electrode terminal 30 or the negative electrode terminal 31 of the plurality of battery cells 20, an electrical signal is input (e.g., input to the processor 700). The processor 700 may determine whether the plurality of battery cells 20 is electrically connected by determining whether the electrical signal is input through the corresponding connector of connectors 200 and recognize that the plurality of connectors 200 is electrically connected to the plurality of battery cells 20 of the corresponding identification information.

When the processor 700 detects the OCV of the plurality of battery cells 20 through the board 300, the processor 700 can match the OCV of one of the plurality of battery cells 20 to the corresponding identification information of the plurality of battery cells 20. In this way, the processor 700 may identify and manage the OCV of each of the plurality of battery cells 20 on the basis of the identification information.

The processor 700 may sequentially measure the OCVs of the plurality of battery cells 20 in a one-to-one manner. For example, the processor 700 may sequentially measure the OCVs of the plurality of battery cells 20 according to a preset measurement order of the plurality of battery cells 20. The processor 700 may set the measurement order of each of the plurality of battery cells 20 using the identification information.

The processor 700 may measure OCVs by grouping the plurality of battery cells 20. For example, the processor 700 may group the plurality of battery cells 20 into a plurality of groups and measure OCVs in a corresponding group according to a measurement order set for each group if the plurality of groups. The processor 700 may set the measurement order of each group using the identification information. The processor 700 may set a measurement order of each of the battery cells 20 in each group using the identification information and measure the OCV of the plurality of battery cells 20 according to the corresponding measurement order.

The processor 700 may also selectively measure at least one of the plurality of battery cells 20. That is, the processor 700 may measure the OCVs of all the plurality of battery cells 20 on the tray 10, or in other embodiments, select one or more among the plurality of battery cells 20 to measure the selected at least one of the plurality of battery cells 20. In this case, a battery cell of the plurality of battery cells 20 whose OCV is to be measured may be set in advance on the basis of the identification information, and the processor 700 may select only a battery cell of the plurality of battery cells 20 of the corresponding identification information to measure an OCV.

The processor 700 may match the measured OCV of the plurality of battery cells 20 to the identification information and transmit each measured OCV to the external device 800 through the communication part 600.

The communication part 600 may transmit the OCVs and the identification information of the plurality of battery cells 20 to the external device 800 through a communication network.

The communication network may employ 3rd generation partnership project (3GPP), long term evolution (LTE), fifth generation (5G), world interoperability for microwave access (WIMAX), wired and wireless Internet, a local area network (LAN), a wireless LAN, a wide area network (WAN), a personal area network (PAN), Bluetooth, Wireless-Fidelity (Wi-Fi), or the like, but the communication network type may vary.

The external device 800 may receive the OCV of each of the plurality of battery cells 20 and the identification information matched to the OCV from the processor 700 through the communication network. The external device 800 may use the OCV of each of the plurality of battery cells 20 to determine a low voltage defect of each of the plurality of battery cells 20.

The external device 800 may be a main system, server, or administrator terminal that manages the plurality of battery cells 20, but may vary.

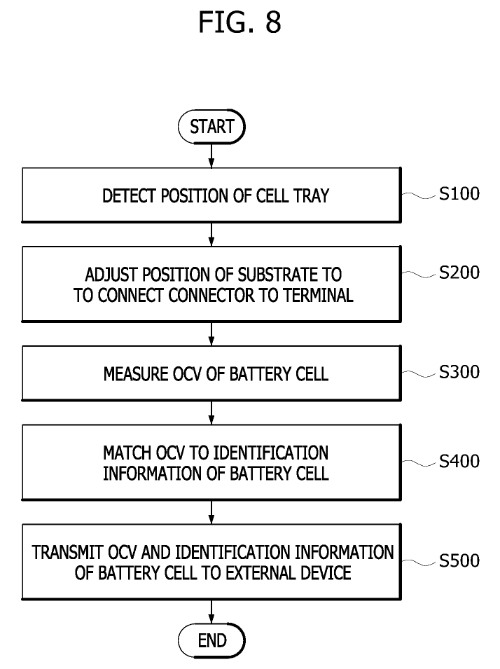

Hereinafter, a method of measuring an OCV of a battery cell according to an embodiment of the present disclosure will be described with reference to FIG. 8.

FIG. 8 is a flowchart illustrating a method of measuring an OCV of a battery cell according to an embodiment of the present disclosure.

Referring to FIG. 8, as the tray 10 reaches a battery cell measurement position immediately in front of an aging rack, the processor 700 moves the substrate 100 to detect an OCV of the plurality of battery cells 20. In this case, the processor 700 may detect a position of the substrate 100 by controlling the substrate position detector 400 (S100).

The processor 700 adjusts the position of the substrate 100 through the substrate position adjustment part 500 according to the position of the substrate 100 detected by the substrate position detector 400 to connect the plurality of connectors 200 of the substrate 100 to the positive electrode terminal 30 and the negative electrode terminal 31 of each of the plurality of battery cells 20 (S200). To this end, the processor 700 may determine whether the position of the substrate 100 detected by the substrate position detector 400 corresponds to a target position. When the position of the substrate 100 is determined to be different from the target position, the processor 700 controls the substrate position adjustment part 500 to allow the substrate 100 to be disposed at the target position.

When the position of the substrate 100 is disposed at the target position, the plurality of connectors 200 of the substrate 100 and the terminals of the plurality of battery cells 20 are connected, and the processor 700 may control the board 300 to measure an OCV of each battery cell of the plurality of battery cells 20 (S300). In this case, the processor 700 may sequentially measure the OCVs of the battery cells in a one-to-one manner or measure the OCVs of the battery cells by grouping the plurality of battery cells 20. In other embodiments, the processor 700 may also selectively measure at least one of the plurality of battery cells 20 as necessary.

The processor 700 may match the measured OCV to identification information of the plurality of battery cells 20 (S400) and transmit the OCV and the identification information of the plurality of battery cells 20 to the external device 800 through a communication network (S500).

Meanwhile, the OCV measurement of the plurality of battery cells 20 may be performed repeatedly in a formation process. For example, the OCV measurement of the plurality of battery cells 20 may be performed not only immediately before the plurality of battery cells 20 is put into the aging rack, but also again after the tray 10 is unloaded from the aging rack after aging so that the OCV measurement may be performed according to a maintenance plan for the plurality of battery cells 20.

The method of measuring an OCV of a battery cell according to an embodiment of the present disclosure may measure the OCVs of the plurality of battery cells in the formation process and transmit the measured OCVs to the external device, thereby shortening a period for screening the battery cell for low-voltage defects.

The term “part” used in the present specification can include a unit implemented in hardware, software, or firmware and can be interchangeably used with terms, for example, including a logic, a logic block, a component, and a circuit. The “part” may be a minimum unit or a portion thereof that performs one or more functions. For example, according to an embodiment, the part may be implemented in the form of an application-specific integrated circuit (ASIC).

In the formation process of a battery cell, the lead time should be reduced while maintaining a quality control level through accurate inspection in a short period of time in order to improve productivity. A process that absolutely takes up much time in the formation process is an aging process.

During the aging process, an OCV of the battery cell is measured using a dedicated battery cell OCV measurement device at specified periods to screen the battery cell for low-voltage defects.

According to the present disclosure, open circuit voltages (OCVs) of a plurality of battery cells can be measured in a formation process and the measured OCVs can be transmitted to an external device, thereby shortening a period for screening the battery cell for low-voltage defects.

The present disclosure is directed to providing an apparatus and method for measuring an open circuit voltage (OCV) of a battery cell that can shorten a period for screening a battery cell for low-voltage defects by measuring OCVs of a plurality of battery cells in a formation process and transmitting the measured OCVs to an external device.

However, effects that can be achieved through the present disclosure are not limited to the above-described effects and other effects that are not described may be clearly understood by those of ordinary skill in the art from the detailed descriptions.

Although the present disclosure has been described with reference to embodiments and drawings illustrating aspects thereof, the present disclosure is not limited thereto. Various modifications and variations can be made by a person skilled in the art to which the present disclosure belongs within the scope of the technical spirit of the present disclosure and the claims and their equivalents, below.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.Accordingly, it will be understood by those of skill in the art that various changes in form and details may be made without departing from the spirit and scope of the present invention as set forth in the following claims.

What is claimed is:

1. An apparatus for measuring an open circuit voltage of a battery cell, the apparatus comprising:
a substrate;
a connector on the substrate;
a board configured to measure the open circuit voltage of the battery cell; and
a processor configured to control the board to measure the open circuit voltage of the battery cell when the connector is connected to a terminal of the battery cell.

2. The apparatus as claimed in claim 1, wherein the substrate is a cover of a tray.

3. The apparatus as claimed in claim 1, further comprising a communication part providing a communication interface with an external device, wherein the processor is further configured to transmit the open circuit voltage of the battery cell to the external device through the communication part.

4. The apparatus as claimed in claim 1, wherein the connector is on a bottom surface of the substrate.

5. The apparatus as claimed in claim 1, wherein the connector is corresponds to a position where the battery cell is on a tray.

6. The apparatus as claimed in claim 1, wherein the processor is further configured to match the open circuit voltage of the battery cell to identification information for the battery cell.

7. The apparatus as claimed in claim 6, wherein the identification information includes position information on a position where the battery cell is on a tray.

8. The apparatus as claimed in claim 1, further comprising a substrate position adjustment part configured to:
adjust a position of the substrate according to a control signal of the processor, and
connect the connector to the terminal of the battery cell.

9. The apparatus as claimed in claim 1, further comprising a substrate position detector configured to detect a position of the substrate and transmit the position to the processor.

10. A method of measuring an open circuit voltage of a battery cell, the method comprising:
controlling, by a processor, a substrate position adjustment part to connect a connector formed on a substrate to a terminal of a battery cell; and
controlling, by the processor, a board to measure an open circuit voltage of the battery cell.

11. The method as claimed in claim 10, wherein connecting the connector to the terminal of the battery cell includes:
detecting, by a substrate position detector, a position of the substrate;
disposing, by the processor, the substrate at a preset target position through the substrate position adjustment part according to the position of the substrate; and
connecting the connector to the terminal of the battery cell.

12. The method as claimed in claim 10, further comprising controlling, by the processor, a communication part to transmit the open circuit voltage of the battery cell to an external device.

13. The method as claimed in claim 12, wherein, transmitting the open circuit voltage of the battery cell to the external device includes the processor matching the open circuit voltage of the battery cell to identification information set for the battery cell.

14. The method as claimed in claim 13, wherein the identification information includes position information on a position where the battery cell is disposed on a tray.

15. The method as claimed in claim 10, wherein the substrate is formed as a cover of a tray.

16. The method as claimed in claim 10, further comprising forming the connector on a bottom surface of the substrate.

17. The method as claimed in claim 10, further comprising forming the connector to correspond to a position where the battery cell is disposed on a tray.
